(19) United States
(12) Patent Application Publication
(10) Pub. No.: US 2025/0263587 A1
(43) Pub. Date: Aug. 21, 2025

(54) METHOD OF MANUFACTURING ADHESIVE MEMBER, METHOD OF MANUFACTURING DISPLAY DEVICE USING THE SAME, AND ELECTRONIC DEVICE INCLUDING DISPLAY DEVICE MANUFACTURED USING THE METHOD

(71) Applicant: Samsung Display Co., LTD., Yongin-si (KR)

(72) Inventors: JEONG-SEOP CHOI, Yongin-si (KR); JEONGIN LEE, Yongin-si (KR); DONG-HUN KANG, Yongin-si (KR); BOO-KAN KI, Yongin-si (KR); YONG-WOO KIM, Yongin-si (KR); HO YUN BYUN, Yongin-si (KR); DONGHYEON LEE, Yongin-si (KR); SEONGSIK CHOI, Yongin-si (KR)

(21) Appl. No.: 19/002,956

(22) Filed: Dec. 27, 2024

(30) Foreign Application Priority Data
Feb. 16, 2024 (KR) 10-2024-0022954

(51) Int. Cl. C09J 5/00; C09J 4/00; C09J 11/06; H10K 59/12

(52) U.S. Cl. CPC C09J 5/00; C09J 4/00; C09J 11/06; H10K 59/1201; C09J 2301/416; C09J 2301/50

(57) ABSTRACT

A method of manufacturing an adhesive member includes: providing a preliminary resin layer including a photopolymerization initiator having a maximum absorption wavelength in a first wavelength range; forming an intermediate resin layer by irradiating the preliminary resin layer with a first ultraviolet light having a wavelength different from the first wavelength range; and forming an adhesive member by irradiating the intermediate resin layer with a second ultraviolet light having a wavelength within the first wavelength range.

This application claims priority to Korean Patent Application No. 10-2024-0022954, filed on Feb. 16, 2024, and all the benefits accruing therefrom under 35 U.S.C. § 119, the content of which in its entirety is herein incorporated by reference.

### BACKGROUND

### 1. Field

The disclosure relates generally to a method of manufacturing an adhesive member. More particularly, the disclosure relates to a method of manufacturing an adhesive member, a method of manufacturing a display device using the same, and an electronic device including a display device manufactured using the method.

### 2. Description of the Related Art

With the development of information technology, the importance of a display device, which is a connection medium between a user and information, is being highlighted. For example, the use of display devices such as liquid crystal display device, organic light-emitting display device, plasma display panel device, quantum dot display device or the like is increasing.

A display device may include a display panel and a functional member disposed on the display panel. Examples of the functional member may include a touch member that detects a user's touch on the display panel, an anti-reflection layer that reduces external light reflection, and a cover window that protects the display panel. An optically clear resin (“OCR”) may be used as an adhesive member to attach the display panel and the functional member. The OCR may be formed by irradiating ultraviolet rays to a resin composition including an oligomer, a monomer, a photopolymerization initiator, etc.

### SUMMARY

Embodiments provide a method of manufacturing an adhesive member with improved adhesive strength.

Embodiments provide a method of manufacturing a display device using the method of manufacturing the adhesive member.

Embodiments provide an electronic device including a display device manufactured using the method of manufacturing the display device.

A method of manufacturing an adhesive member in an embodiment of the disclosure includes: providing a preliminary resin layer including a photopolymerization initiator having a maximum absorption wavelength in a first wavelength range; forming an intermediate resin layer by irradiating the preliminary resin layer with a first ultraviolet light having a wavelength different from the first wavelength range; and forming an adhesive member by irradiating the intermediate resin layer with a second ultraviolet light having a wavelength within the first wavelength range.

In an embodiment, a second starting point at which the second ultraviolet light is irradiated may be spaced apart from a first starting point at which the first ultraviolet light is irradiated by a predetermined time interval. The predetermined time interval may be determined based on a fluidity of the preliminary resin layer.

In an embodiment, in the irradiating the second ultraviolet light to the intermediate resin layer, the first ultraviolet light having the wavelength different from the first wavelength range may not be irradiated.

In an embodiment, in the irradiating the second ultraviolet light to the intermediate resin layer, the first ultraviolet light having the wavelength different from the first wavelength range may be simultaneously irradiated to the intermediate resin layer.

In an embodiment, in the irradiating the first ultraviolet light, the first ultraviolet light includes sub-ultraviolet lights so that a sub-ultraviolet light having a wavelength smaller than the first wavelength range and a sub-ultraviolet light having a wavelength greater than the first wavelength range among the sub-ultraviolet lights may be simultaneously irradiated.

In an embodiment, the irradiating the first ultraviolet light and the second ultraviolet light may be performed by an ultraviolet light irradiating apparatus including a plurality of first ultraviolet emission units which irradiate the first ultraviolet light and a plurality of second ultraviolet emission units which irradiate the second ultraviolet light.

In an embodiment, the ultraviolet light irradiating apparatus may irradiate the first ultraviolet light while the ultraviolet light irradiating apparatus is fixed on the preliminary resin layer and may irradiate the second ultraviolet light while the ultraviolet light irradiating apparatus is fixed on the intermediate resin layer.

In an embodiment, the ultraviolet light irradiating apparatus may irradiate the first ultraviolet light to an entirety of an area of the preliminary resin layer and may irradiate the second ultraviolet light to an entirety of an area of the intermediate resin layer.

In an embodiment, the plurality of first ultraviolet emission units may be disposed in a matrix form in a plan view. The plurality of second ultraviolet emission units may be disposed in a matrix form in the plan view.

A method of manufacturing a display device in an embodiment of the disclosure includes: forming a preliminary resin layer including a photopolymerization initiator which has a maximum absorption wavelength in a first wavelength range on a display panel including a substrate, a display element layer, and an encapsulation layer; forming an intermediate resin layer by irradiating the preliminary resin layer with a first ultraviolet light having a wavelength different from the first wavelength range; forming an adhesive member by irradiating the intermediate resin layer with a second ultraviolet light having a wavelength within the first wavelength range; and forming a functional member on the adhesive member.

In an embodiment, a starting point at which the second ultraviolet light is irradiated may be spaced apart from a starting point at which the first ultraviolet light is irradiated by a predetermined time interval. The predetermined time interval may be determined based on a fluidity of the preliminary resin layer.

In an embodiment, in the irradiating the second ultraviolet light to the intermediate resin layer, the first ultraviolet light having the wavelength different from the first wavelength range may not be irradiated.

In an embodiment, in the irradiating the second ultraviolet light to the intermediate resin layer, the first ultraviolet light having the wavelength different from the first wavelength range may be simultaneously irradiated to the intermediate resin layer.

In an embodiment, in the irradiating the first ultraviolet light, the first ultraviolet light includes sub-ultraviolet lights so that a sub-ultraviolet light having a wavelength smaller than the first wavelength range and a sub-ultraviolet light having a wavelength greater than the first wavelength range among the sub-ultraviolet lights may be simultaneously irradiated.

In an embodiment, the preliminary resin layer may be formed using an inkjet printing method.

In an embodiment, the functional member may include at least one of a touch member, an anti-reflection layer, and a cover window.

In an embodiment, the irradiating the first ultraviolet light and the irradiating the second ultraviolet light may be performed by an ultraviolet light irradiating apparatus including a plurality of first ultraviolet emission units which irradiate the first ultraviolet light and a plurality of second ultraviolet emission units which irradiate the second ultraviolet light.

In an embodiment, the ultraviolet light irradiating apparatus may irradiate the first ultraviolet light while the ultraviolet light irradiating apparatus is fixed on the preliminary resin layer and may irradiate the second ultraviolet light while the ultraviolet light irradiating apparatus is fixed on the intermediate resin layer.

In an embodiment, the ultraviolet light irradiating apparatus may irradiate the first ultraviolet light to an entirety of the area of the preliminary resin layer and may irradiate the second ultraviolet light to an entirety of the area of the intermediate resin layer.

In an embodiment, the plurality of first ultraviolet emission units may be disposed in a matrix form in a plan view. The plurality of second ultraviolet emission units may be disposed in a matrix form in the plan view.

An electronic device in an embodiment of the disclosure includes: a display device manufacturing using the method of manufacturing the display device described above; and a power supply configured to provide power to the display device.

A method of manufacturing an adhesive member in an embodiment of the disclosure may include providing a preliminary resin layer including an oligomer, a monomer, and a photopolymerization initiator which has a maximum absorption wavelength in a first wavelength range, forming an intermediate resin layer by irradiating the preliminary resin layer with a first ultraviolet light having a wavelength different from the first wavelength range, and forming an adhesive member by irradiating the intermediate resin layer with a second ultraviolet light having a wavelength within the first wavelength range. In other words, the first ultraviolet light having a wavelength different from the maximum absorption wavelength of the photopolymerization initiator may be irradiated first, and the second ultraviolet light having a wavelength within a range of the maximum absorption wavelength of the photopolymerization initiator may be irradiated subsequently.

In this case, compared to a case where the first ultraviolet light and the second ultraviolet light are irradiated simultaneously from the beginning, the photopolymerization initiator may be decomposed relatively slowly. As the photopolymerization initiator decomposes relatively slowly, a length of a polymer chain formed by covalently bonding the oligomer and the monomer may be relatively increased. As a result, the adhesive strength of the adhesive member including the polymer may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an embodiment of a display device according to the disclosure.

FIG. 2 is a view illustrating a bent shape of the display device of FIG. 1.

FIG. 3 is a cross-sectional view illustrating the display device of FIG. 1.

FIG. 4 is a cross-sectional view taken along line I-I′ of FIG. 1.

FIG. 5 is a flowchart illustrating an embodiment of a method of manufacturing a display device according to the disclosure.

FIGS. 6, 7, 8, 9, 10, 11, 12, 13, 14, and 15 are views illustrating the method of manufacturing the display device of FIG. 5.

FIG. 16 is a view illustrating a strength of adhesive force of an adhesive member according to a comparative example.

FIG. 17 is a view illustrating an embodiment of a strength of adhesive force of an adhesive member.

FIG. 18 is a block diagram illustrating an embodiment of an electronic device according to the disclosure.

FIG. 19 is a view illustrating an example in which the electronic device of FIG. 18 is implemented as a smart phone.

### DETAILED DESCRIPTION

Hereinafter, embodiments of the disclosure will be described in detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

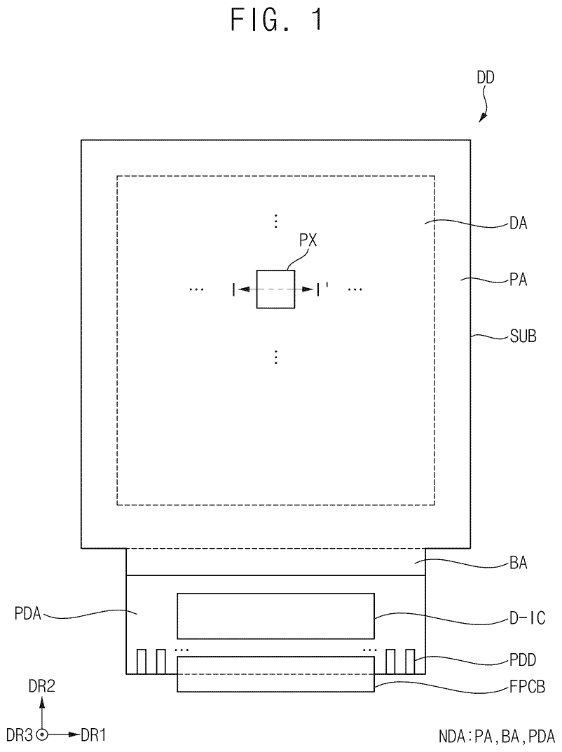

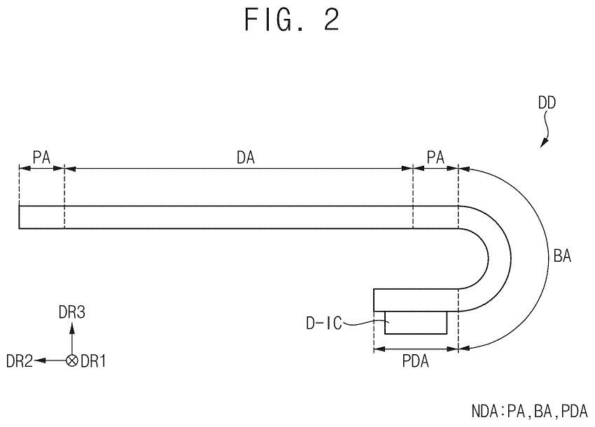

FIG. 1 is a plan view illustrating an embodiment of a display device according to the disclosure. FIG. 2 is a view illustrating a bent shape of the display device of FIG. 1.

In this specification, a plane may be defined by a first direction DR1 and a second direction DR2 intersecting the first direction DR1. In an embodiment, the first direction DR1 and the second direction DR2 may be perpendicular to each other, for example. A direction normal to the plane, that is, a thickness direction of a display device DD may be a third direction DR3. In other words, the third direction DR3 may be perpendicular to each of the first direction DR1 and the second direction DR2.

Referring to FIGS. 1 and 2, the display device DD in an embodiment of the disclosure may include a substrate SUB, a driving chip D-IC, a plurality of pads PDD, and a circuit board FPCB.

The substrate SUB may include a display area DA and a non-display area NDA. The display area DA may be defined as an area that displays an image by generating light or adjusting the transmittance of light provided from an external light source. A plurality of pixels PX may be disposed in the display area DA. Each of the pixels PX may generate light in response to a driving signal. In an embodiment, the pixels PX may be arranged in a matrix along the first direction DR1 and the second direction DR2, for example. However, the disclosure is not limited thereto, and the pixels PX may be arranged in various other forms.

The non-display area NDA may be defined as an area that does not display an image. The non-display area NDA may include a peripheral area PA, a bending area BA, and a pad area PDA.

The peripheral area PA may be disposed at a periphery of the display area DA. The peripheral area PA may surround at least a portion of the display area DA. In an embodiment, the peripheral area PA may surround an entirety of the display area DA in a plan view, for example.

The bending area BA may extend from one side of the peripheral area PA, and may be bent downward. In other words, as illustrated in FIG. 2, the substrate SUB may be bent about a reference axis parallel to the first direction DR1 in the bending area BA. In this case, the pad area PDA may be disposed on a lower surface of the display device DD. The pad area PDA may extend from the bending area BA and may be disposed under the display area DA or under the peripheral area PA. When the display device DD is unfolded, the bending area BA may be disposed between the peripheral area PA and the pad area PDA.

The pad area PDA may be disposed at one side (e.g., lower side in FIG. 1) of the display area DA. The pad area PDA may be spaced apart from the display area DA in a plan view with the bending area BA between the display area DA and the pad area PDA. In an embodiment, the pad area PDA and the display area DA may be spaced apart from each other in the second direction DR2, for example. The pad area PDA may extend in the first direction DR1. The pads PDD may be disposed in the pad area PDA.

The driving chip D-IC may be disposed in the pad area PDA on the substrate SUB. In an embodiment, the driving chip D-IC may be disposed (e.g., mounted) in the pad area PDA on the substrate SUB, for example. However, the disclosure is not limited thereto, and the driving chip D-IC may be disposed (e.g., mounted) on the circuit board FPCB as a chip on film (“COF”) type.

The driving chip D-IC may be connected to the pads PDD through an anisotropic conductive film (“ACF”). The driving chip D-IC may provide the driving signal to the pixels PX. The drive signal may include various signals to drive the pixels PX, such as a driving voltage, a control signal, a data signal, etc.

The circuit board FPCB may be disposed in the pad area PDA on the substrate SUB. The circuit board FPCB may be connected to the pads PDD through an anisotropic conductive film. In an embodiment, the circuit board FPCB may be a flexible printed circuit board, for example.

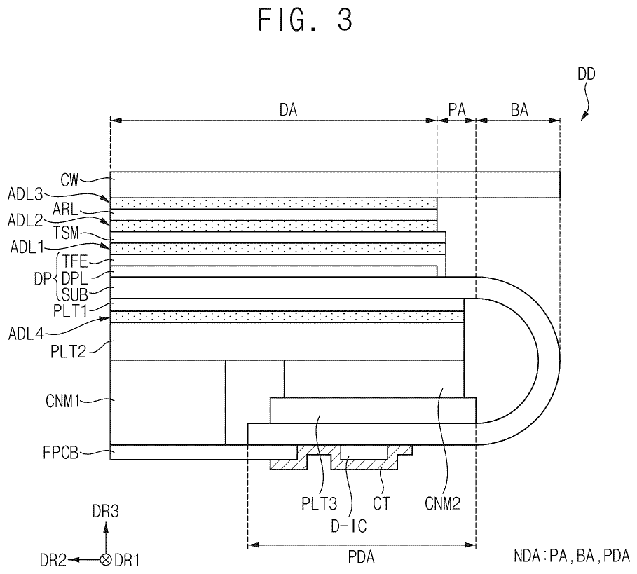

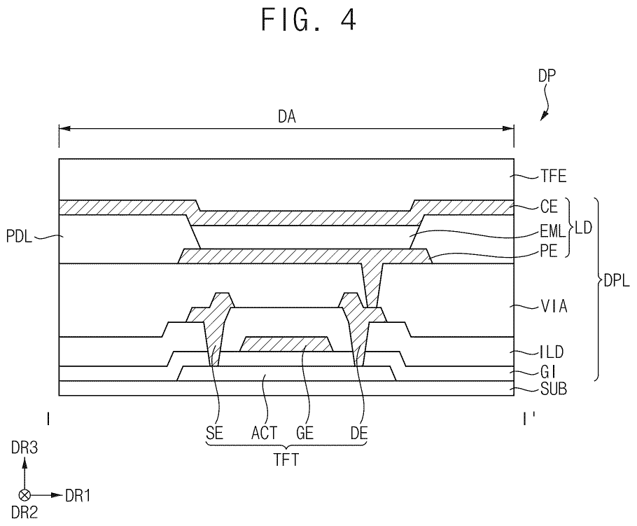

FIG. 3 is a cross-sectional view illustrating the display device of FIG. 1. FIG. 4 is a cross-sectional view taken along line I-I′ of FIG. 1.

Referring to FIGS. 3 and 4, the display device DD in an embodiment of the disclosure may include a display panel DP, a first adhesive member ADL1, a touch member TSM, a second adhesive member ADL2, an anti-reflection layer ARL, a third adhesive member ADL3, a cover window CW, first to third plates PLT1, PLT2, and PLT3, a fourth adhesive member ADL4, first and second connecting members CNM1 and CNM2, the driving chip D-IC, the circuit board FPCB, and a cover tape CT. The display panel DP may include the substrate SUB, a display element layer DPL, and an encapsulation layer TFE.

The substrate SUB may be bent about the reference axis parallel to the first direction DR1 in the bending area BA. The substrate SUB may include a transparent material or an opaque material. The substrate SUB may include or consist of a transparent resin substrate. A polyimide substrate may be an embodiment of the transparent resin substrate. In this case, the polyimide substrate may include a first organic layer, a first barrier layer, a second organic layer, etc. In an alternative embodiment, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in any combinations with each other.

The display element layer DPL may be disposed on the substrate SUB. Specifically, as illustrated in FIG. 4, the display element layer DPL may include a thin film transistor TFT, a gate insulating layer GI, an inter-layer insulating layer ILD, a via-insulating layer VIA, a light-emitting element LD, and a pixel defining layer PDL. The thin film transistor TFT may include an active pattern ACT, a gate electrode GE, a source electrode SE, and a drain electrode DE. The light-emitting element LD may include a pixel electrode PE, a light-emitting layer EML, and a common electrode CE.

The active pattern ACT may be disposed on the substrate SUB. The active pattern ACT may include an oxide semiconductor, a silicon semiconductor, an organic semiconductor, etc. In an embodiment, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc., for example. These may be used alone or in any combinations with each other. The silicon semiconductor may include amorphous silicon, polycrystalline silicon, etc. The active pattern ACT may include a source area, a drain area, and a channel area between the source area and the drain area.

The gate insulating layer GI may be disposed on the active pattern ACT and the substrate SUB. In an embodiment, the gate insulating layer GI may cover the active pattern ACT on the substrate SUB and may be disposed along the profile of the active pattern ACT with a substantially uniform thickness, for example. The gate insulating layer GI may include an inorganic insulating material. In embodiments, the inorganic insulating material that may be used as the gate insulating layer GI may include silicon oxide (SiOₓ), silicon nitride (SiNₓ), silicon oxynitride (SiOₓN_{y}), etc. These may be used alone or in any combinations with each other.

The gate electrode GE may be disposed on the gate insulating layer GI. The gate electrode GE may overlap the channel area of the active pattern ACT. The gate electrode GE may include a metal, an alloy, a metal nitride, a conductive metal oxide, a transparent conductive material, etc. In embodiments, material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other.

The inter-layer insulating layer ILD may be disposed on the gate electrode GE and the gate insulating layer GI. In an embodiment, the inter-layer insulating layer ILD may cover the gate electrode GE on the gate insulating layer GI and may be disposed along the profile of the gate electrode GE with a substantially uniform thickness, for example. The inter-layer insulating layer ILD may include an inorganic insulating material. In embodiments, the inorganic insulating material that may be used as the inter-layer insulating layer ILD may include silicon oxide (SiOₓ), silicon nitride (SiNₓ), silicon oxynitride (SiOₓN_{y}), etc. These may be used alone or in any combinations with each other.

The source electrode SE and the drain electrode DE may be disposed on the inter-layer insulating layer ILD. The source electrode SE may be connected to the source area of the active pattern ACT through a contact hole defined through the gate insulating layer GI and the inter-layer insulating layer ILD. The drain electrode DE may be connected to the drain area of the active pattern ACT through a contact hole defined through the gate insulating layer GI and the inter-layer insulating layer ILD. Each of the source electrode SE and the drain electrode DE may include a metal, an alloy, a metal nitride, a conductive metal oxide, a transparent conductive material, etc. These may be used alone or in any combinations with each other.

Accordingly, the thin film transistor TFT including the active pattern ACT, the gate electrode GE, the source electrode SE, and the drain electrode DE may be formed.

The via-insulating layer VIA may be disposed on the inter-layer insulating layer ILD. In an embodiment, the via-insulating layer VIA may be disposed on the inter-layer insulating layer ILD with a relatively thick thickness to sufficiently cover the source electrode SE and the drain electrode DE, for example. The via-insulating layer VIA may include an organic insulating material. In embodiments, the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, etc. These may be used alone or in any combinations with each other.

The pixel electrode PE may be disposed on the via-insulating layer VIA. The pixel electrode PE may be connected to the drain electrode DE through a contact hole defined through the via-insulating layer VIA. As a result, the pixel electrode PE may be electrically connected to the thin film transistor TFT. The pixel electrode PE may include a metal, an alloy, a metal nitride, a conductive metal oxide, a transparent conductive material, etc. These may be used alone or in any combinations with each other. In an embodiment, the pixel electrode PE may serve as an anode electrode, for example.

The pixel defining layer PDL may be disposed on the via-insulating layer VIA and the pixel electrode PE. The pixel defining layer PDL may cover an edge of the pixel electrode PE and may expose an upper surface of the pixel electrode PE. The pixel defining layer PDL may include an organic insulating material. In embodiments, the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, etc. These may be used alone or in any combinations with each other.

The light-emitting layer EML may be disposed on the pixel electrode PE. Specifically, the light-emitting layer EML may be disposed on the upper surface of the pixel electrode PE exposed by the pixel defining layer PDL. The light-emitting layer EML may emit light having a predetermined color (e.g., red, green and/or blue). In an embodiment, the light-emitting layer EML may include one or both of an organic light-emitting material and a quantum dot.

In an embodiment, the light-emitting layer EML may have a single-layer structure including one light-emitting layer, for example. In an alternative embodiment, the light-emitting layer EML may have a tandem structure in which a plurality of light-emitting layers is stacked.

The common electrode CE may be disposed on the pixel defining layer PDL and the light-emitting layer EML. The common electrode CE may cover the pixel defining layer PDL and the light-emitting layer EML and may be disposed along the profiles of the pixel defining layer PDL and the light-emitting layer EML with a substantially uniform thickness. In an embodiment, the common electrode CE may include a metal, an alloy, a metal nitride, a conductive metal oxide, a transparent conductive material, etc., for example. These may be used alone or in any combinations with each other. In an embodiment, the common electrode CE may serve as a cathode electrode, for example.

Accordingly, the light-emitting element LD including the pixel electrode PE, the light-emitting layer EML, and the common electrode CE may be formed.

The encapsulation layer TFE may be disposed on the common electrode CE. The encapsulation layer TFE may prevent impurities, moisture, etc. from penetrating into the light-emitting element LD from the outside. The encapsulation layer TFE may include at least one inorganic encapsulation layer and at least one organic encapsulation layer. Specifically, the encapsulation layer TFE may have a structure in which the inorganic encapsulation layer and the organic encapsulation layer are alternately stacked. In an embodiment, the inorganic encapsulation layer may include silicon oxide (SiOₓ), silicon nitride (SiNₓ), silicon oxynitride (SiOₓN_{y}), etc., for example. These may be used alone or in any combinations with each other. In an embodiment, the organic encapsulation layer may include a cured polymer such as polyacrylate, for example.

Although the display device DD of the disclosure is described by limiting the organic light-emitting display device, the configuration of the disclosure is not limited thereto. In other embodiments, the display device DD may include a liquid crystal display (“LCD”) device, a field emission display (“FED”) device, a plasma display panel (“PDP”) device, an electrophoretic image display (“EPD”) device, an inorganic light-emitting display device, or a quantum dot display device.

As illustrated in FIG. 3, the touch member TSM may be disposed on the display panel DP. The touch member TSM may overlap the display area DA and a portion of the peripheral area PA. The touch member TSM may be attached to an upper surface of the display panel DP through the first adhesive member ADL1. In an alternative embodiment, the touch member TSM may be disposed directly on the display panel DP. In other words, the touch member TSM may be disposed directly on the display panel DP without an adhesive member.

The touch member TSM may detect a user's touch. In an embodiment, the touch member TSM may acquire coordinate information based on an external input, such as the user's touch, for example. The touch member TSM may detect the external input by a mutual capacitance method and/or a self-capacitance method.

The first adhesive member ADL1 may be disposed between the encapsulation layer TFE and the touch member TSM. The first adhesive member ADL1 may overlap the display area DA and a portion of the peripheral area PA. The first adhesive member ADL1 may attach the encapsulation layer TFE and the touch member TSM.

The anti-reflection layer ARL may be disposed in the display area DA on the touch member TSM. The anti-reflection layer ARL may be attached to an upper surface of the touch member TSM through the second adhesive member ADL2. The anti-reflection layer ARL may reduce an external light reflection of the display device DD. The anti-reflection layer ARL may include a polarizer and/or a phase retarder. In an alternative embodiment, the anti-reflection layer ARL may include color filters and a black matrix disposed between the color filters. The color filters may be arranged taking into account light-emitting colors of the light-emitting element LD included in the display element layer DPL.

The second adhesive member ADL2 may be disposed between the touch member TSM and the anti-reflection layer ARL. The second adhesive member ADL2 may overlap the display area DA. The second adhesive member ADL2 may attach the touch member TSM and the anti-reflection layer ARL.

The cover window CW may be disposed on the anti-reflection layer ARL. The cover window CW may be attached to an upper surface of the anti-reflection layer ARL through the third adhesive member ADL3. The cover window CW may cover and protect the display panel DP. The cover window CW may include a transparent material. In an embodiment, the cover window CW may include glass or plastic, for example.

The third adhesive member ADL3 may be disposed between the anti-reflection layer ARL and the cover window CW. The third adhesive member ADL3 may overlap the display area DA. The third adhesive member ADL3 may attach the anti-reflection layer ARL and the cover window CW.

Each of the first adhesive member ADL1, the second adhesive member ADL2, and the third adhesive member ADL3 may include a pressure sensitive adhesive (“PSA”) film, an optically clear adhesive (“OCA”) film, or an optically clear resin (“OCR”). In an embodiment, each of the first adhesive member ADL1, the second adhesive member ADL2, and the third adhesive member ADL3 may include an optically clear resin.

The first plate PLT1 may be disposed under the substrate SUB. The first plate PLT1 may complement the rigidity of the substrate SUB. The first plate PLT1 may include an organic material. In embodiments, the organic material that may be used as the first plate PLT1 may include polyethylene terephthalate (“PET”), polyimide (“PI”), polyethylene naphthalate (“PEN”), etc. However, the disclosure is not limited thereto.

The second plate PLT2 may be disposed under the first plate PLT1. The second plate PLT2 may be attached to a lower surface of the first plate PLT1 through the fourth adhesive member ADL4. The second plate PLT2 may protect the substrate SUB from an external impact. In an embodiment, the second plate PLT2 may include a foam tape or a foam pad, for example.

The fourth adhesive member ADL4 may be disposed between the first plate PLT1 and the second plate PLT2. The fourth adhesive member ADL4 may overlap the display area DA and a portion of the peripheral area PA. The fourth adhesive member ADL4 may attach the first plate PLT1 and the second plate PLT2. In an embodiment, the fourth adhesive member ADL4 may include a pressure sensitive adhesive film, an optically clear adhesive film, or an optically clear resin, for example. In an embodiment, the fourth adhesive member ADL4 may include a pressure sensitive adhesive film.

The third plate PLT3 may be disposed under the substrate SUB in the pad area PDA. The third plate PLT3 may complement the rigidity of the substrate SUB. The third plate PLT3 may include an organic material. In embodiments, the organic material that may be used as the third plate PLT3 may include polyethylene terephthalate (“PET”), polyimide (“PI”), polyethylene naphthalate (“PEN”), etc. However, the disclosure is not limited thereto.

The first connecting member CNM1 may be disposed between the second plate PLT2 and the circuit board FPCB. The first connecting member CNM1 may directly contact the second plate PLT2 and the circuit board FPCB, and may fix the circuit board FPCB.

The second connecting member CNM2 may be disposed between the second plate PLT2 and the third plate PLT3. The second connecting member CNM2 may directly contact the second plate PLT2 and the third plate PLT3, and may maintain the substrate SUB in a bent state.

The driving chip D-IC may be disposed in the pad area PDA on the substrate SUB. The driving chip D-IC may be connected to the pads (PDD, refer to FIG. 1) disposed in the pad area PDA on the substrate SUB through an anisotropic conductive film.

The circuit board FPCB may be disposed in the pad area PDA on the substrate SUB. The circuit board FPCB may be connected to the pads through an anisotropic conductive film.

The cover tape CT may be disposed in the pad area PDA on the substrate SUB. The cover tape CT may cover the circuit board FPCB and the driving chip D-IC. The cover tape CT may protect the driving chip D-IC from an external impact. In addition, the cover tape CT may shield electromagnetic interference noise generated by the circuit board FPCB. In an embodiment, the cover tape CT may include copper (Cu) or aluminum (Al), for example.

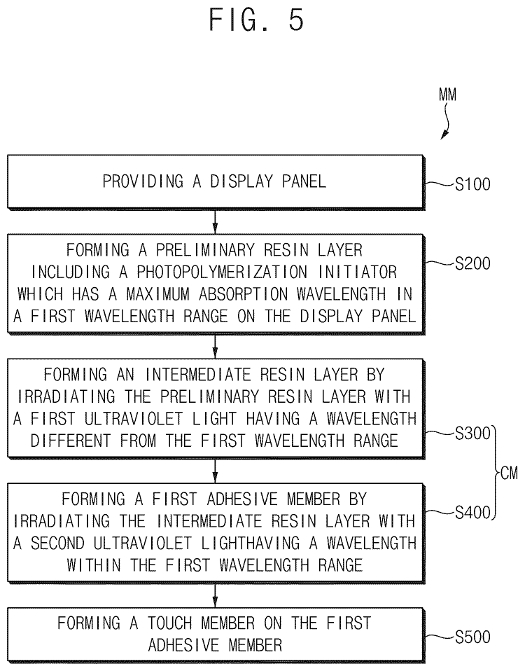

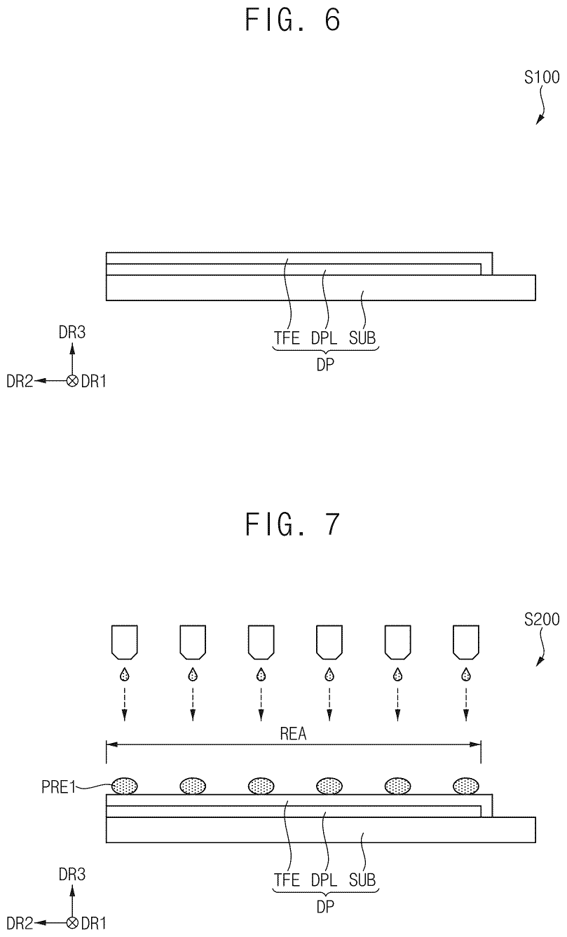

FIG. 5 is a flowchart illustrating an embodiment of a method of manufacturing a display device according to the disclosure. FIGS. 6, 7, 8, 9, 10, 11, 12, 13, 14, and 15 are views illustrating the method of manufacturing the display device of FIG. 5. Hereinafter, descriptions of a method of forming the first to third plates PLT1, PLT2, and PLT3, the first connecting member CNM1, and the second connecting member CNM2 of FIG. 2, which are disposed under the substrate SUB, will be omitted. In addition, descriptions of a method of forming the driving chip D-IC, the circuit board FPCB, and the cover tape CT of FIG. 2, which are disposed on the substrate SUB in the pad area PDA, will be omitted.

Referring to FIGS. 2 and 5, a method MM of manufacturing a display device in an embodiment of the disclosure may include providing the display panel DP (S100), forming a preliminary resin layer including a photopolymerization initiator, which has a maximum absorption wavelength in a first wavelength range, on the display panel DP (S200), forming an intermediate resin layer by irradiating the preliminary resin layer with a first ultraviolet light having a wavelength different from the first wavelength range (S300), forming a first adhesive member by irradiating the intermediate resin layer with a second ultraviolet light having a wavelength within the first wavelength range (S400), and forming the touch member TSM on the first adhesive member (S500).

Referring to FIG. 6, the display panel DP may be provided (S100).

The display panel DP may include the substrate SUB, the display element layer DPL, and the encapsulation layer TFE. The display element layer DPL may be disposed on the substrate SUB. The display element layer DPL may include the thin film transistor TFT, the gate insulating layer GI, the inter-layer insulating layer ILD, the via-insulating layer VIA, the light-emitting element LD, and the pixel defining layer PDL which are illustrated in FIG. 4. The encapsulation layer TFE may be disposed on the display element layer DPL. The encapsulation layer TFE may cover the display element layer DPL.

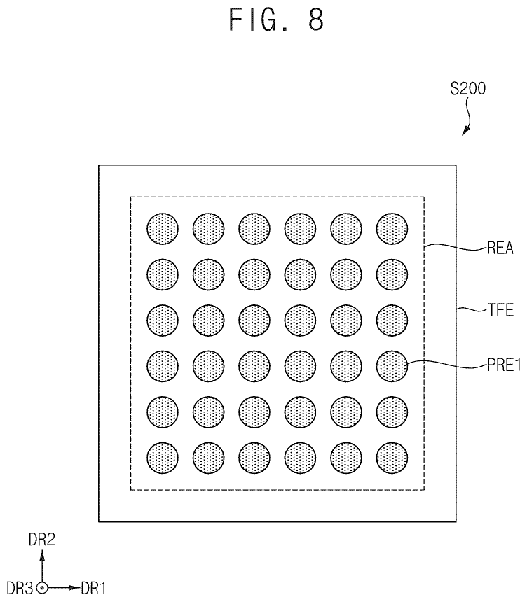

Referring to FIGS. 7 and 8, a preliminary resin layer PRE1 including a photopolymerization initiator, which has a maximum absorption wavelength in a first wavelength range, may be formed on the display panel DP (S200).

The preliminary resin layer PRE1 may be formed on the display panel DP. Specifically, the preliminary resin layer PRE1 may be formed on the encapsulation layer TFE. In an embodiment, the preliminary resin layer PRE1 may be formed using an inkjet printing method. Specifically, the preliminary resin layer PRE1 may be applied to a resin area REA on the encapsulation layer TFE through an inkjet printing method. The resin area REA may be defined as an area where the preliminary resin layer PRE1 is cured to form a first adhesive member (ADL1, refer to FIG. 13).

The preliminary resin layer PRE1 may include an oligomer, a monomer, a photopolymerization initiator, and a solvent. When the preliminary resin layer PRE1 is irradiated with ultraviolet light, the photopolymerization initiator may initiate a polymerization reaction between the oligomer and the monomer. The photopolymerization initiator may include at least one of a radical type initiator and a cationic type initiator.

In an embodiment, the radical type initiator may include an oxime ester-based initiator, an acetophenone-based initiator, an acyl phosphine oxide-based initiator, a phosphinate-based initiator, etc., for example. The acetophenone-based initiator may include 2-methyl-1-[(4-methylthio)phenyl]-2-(4-morpholinyl)-1-propanol, 2-benzyl-2-(dimethylamino)-4-morpholinobutyrophenone, 2-(4-methylbenzyl)-2-(dimethylamino)-1-(4-morpholinophenyl) butan-1-one, etc. The acyl phosphine oxide-based initiator may include 2,4,6-trimethylbenzoyl diphenyl phosphine oxide, bis-2,4,6-trimethylbenzoyl-phenyl phosphine oxide, bis-2,4,4-trimethyl-benzyl-phosphine oxide, etc. The phosphinate-based initiator may include ethyl-(2,4,6-trimethylbenzoyl)phenyl phosphinate. These may be used alone or in any combinations with each other.

In an embodiment, the cationic type initiator may include aryl sulfonium hexafluoroantimonium salt, aryl iodium hexafluoroantimonium salt, aryl sulfonium hexafluorophosphate salt, diphenyliodonium hexafluoroantimonium salt, diphenyliodonium hexafluorophosphate salt, diaryliodonium hexafluorophosphate salt, etc., for example. These may be used alone or in any combinations with each other.

The photopolymerization initiator may have a maximum absorption wavelength in the first wavelength range. Here, a maximum absorption wavelength may refer to a wavelength having a maximum value of light absorption in the light absorption spectrum of the photopolymerization initiator. In an embodiment, the first wavelength range may be about 360 nanometers to about 370 nanometers, for example. However, the disclosure is not limited thereto, and a maximum absorption wavelength may have a different wavelength range depending on the type of the photopolymerization initiator.

In an embodiment, the solvent may include a ketone-based solvent or an ether-based solvent, for example. The ketone-based solvent may include methyl ethyl ketone, acetophenone, cyclopentanone, ethyl isopropyl ketone, 2-hexanone, isophorone, mesityl oxide, methyl isobutyl ketone, 3-methyl-2-pentanone, 2-pentanone, 3-pentanone, etc. The ether-based solvent may include cyclopentyl methyl ether (“CPME”), diethylene glycol diethyl ether, dimethoxymethane, methyl tert-butyl ether, 2-(2-methoxyethoxy) ethanol, propylene glycol ether, etc. These may be used alone or in any combinations with each other.

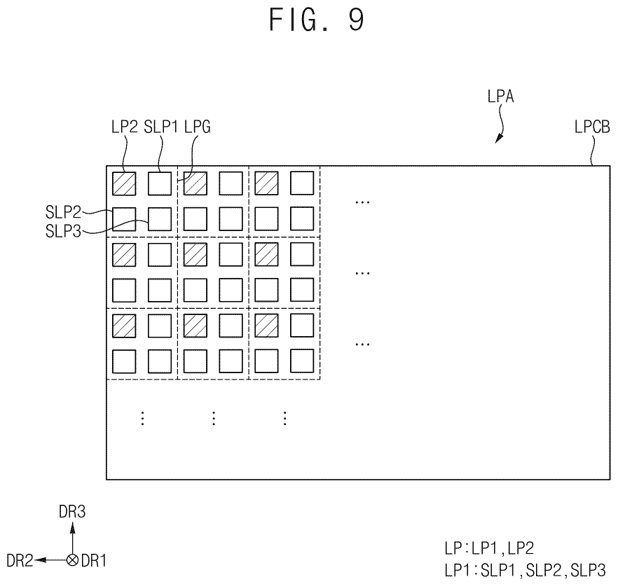

Referring to FIGS. 9, 10, and 11, an intermediate resin layer PRE2 may be formed by irradiating the preliminary resin layer PRE1 with a first ultraviolet light L1 having a wavelength different from the first wavelength range (S300).

As illustrated in FIG. 9, an ultraviolet light irradiating apparatus LPA may be provided to irradiate the preliminary resin layer PRE1 with ultraviolet light. The ultraviolet light irradiating apparatus LPA may include an emission circuit board LPCB and a plurality of ultraviolet emission units LP disposed (e.g., mounted) on the light-emitting circuit board LPCB.

The emission circuit board LPCB may provide power to drive the ultraviolet emission units LP. In an embodiment, the emission circuit board LPCB may be a printed circuit board, for example.

Each of the ultraviolet emission units LP may include an active layer, an n-type semiconductor layer, and a p-type semiconductor layer, and may emit ultraviolet light of a wavelength (e.g., a predetermined wavelength) according to the composition of the active layer. That is, each of the ultraviolet emission units LP may be set to generate ultraviolet light of a desired wavelength by adjusting the composition of the active layer. The ultraviolet emission units LP may include a plurality of first ultraviolet emission units LP1 and a plurality of second ultraviolet emission units LP2.

The first ultraviolet emission units LP1 may be disposed repeatedly along the first direction DR1 and the second direction DR2. In an embodiment, the first ultraviolet emission units LP1 may be disposed in a matrix form in a plan view, for example. The first ultraviolet emission units LP1 may irradiate the preliminary resin layer PRE1 with the first ultraviolet light L1 having a wavelength different from the first wavelength range. Each of the first ultraviolet emission units LP1 may include a first sub-emission unit SLP1, a second sub-emission unit SLP2, and a third sub-emission unit SLP3.

The first sub-emission unit SLP1, the second sub-emission unit SLP2, and the third sub-emission unit SLP3 may respectively emit ultraviolet lights (also referred to as sub-ultraviolet lights of the first ultraviolet light L1) of different wavelengths. The first sub-emission unit SLP1 may irradiate ultraviolet light (also referred to as a sub-ultraviolet light of the first ultraviolet light L1) having a wavelength smaller than the first wavelength range. Each of the second sub-emission unit SLP2 and the third sub-emission unit SLP3 may irradiate ultraviolet light (also referred to as a sub-ultraviolet light of the first ultraviolet light L1) having a wavelength greater than the first wavelength range. In an embodiment, when the first wavelength range is about 360 nanometers to about 370 nanometers, the first sub-emission unit SLP1 may emit ultraviolet light having a wavelength of about 310 nanometers, the second sub-emission unit SLP2 may emit ultraviolet light having a wavelength of about 385 nanometers, and the third sub-emission unit SLP3 may emit ultraviolet light having a wavelength of about 405 nanometers, for example.

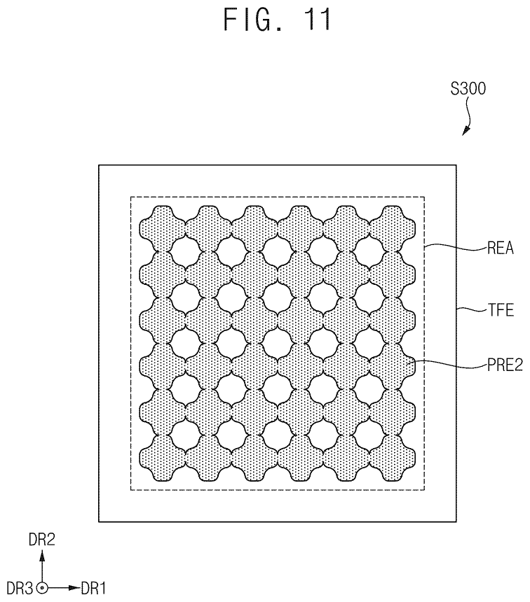

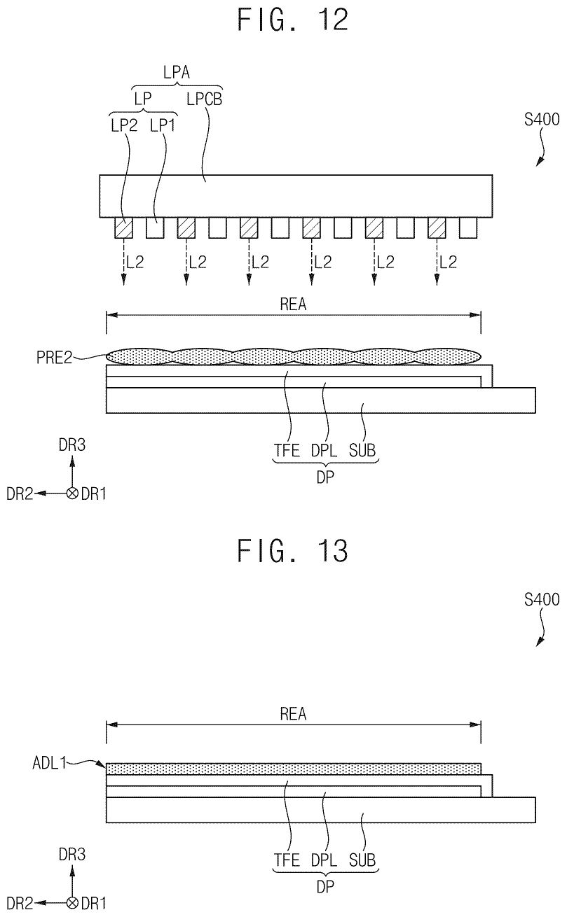

The second ultraviolet emission units LP2 may be disposed repeatedly along the first direction DR1 and the second direction DR2. In an embodiment, the second ultraviolet emission units LP2 may be disposed in a matrix form in a plan view, for example. The second ultraviolet emission units LP2 may irradiate a second ultraviolet light (L2, refer to FIG. 12) having a wavelength within the first wavelength range. In an embodiment, when the first wavelength range is about 360 nanometers to about 370 nanometers, the second ultraviolet emission units LP2 may emit ultraviolet light having a wavelength of about 365 nanometers, for example.

In an embodiment, an ultraviolet emission group LPG including the first sub-emission unit SLP1, the second sub-emission unit SLP2, the third sub-emission unit SLP3, and the second ultraviolet emission unit LP2 may be defined. The ultraviolet emission groups LPG may be disposed in a matrix form along the first direction DR1 and the second direction DR2. Within one ultraviolet emission group LPG, the first sub-emission unit SLP1, the second sub-emission unit SLP2, the third sub-emission unit SLP3, and the second ultraviolet emission unit LP2 may be spaced apart from each other. However, the disclosure is not limited thereto, and within one ultraviolet emission group LPG, the first sub-emission unit SLP1, the second sub-emission unit SLP2, the third sub-emission unit SLP3, and the second ultraviolet emission unit LP2 may contact each other.

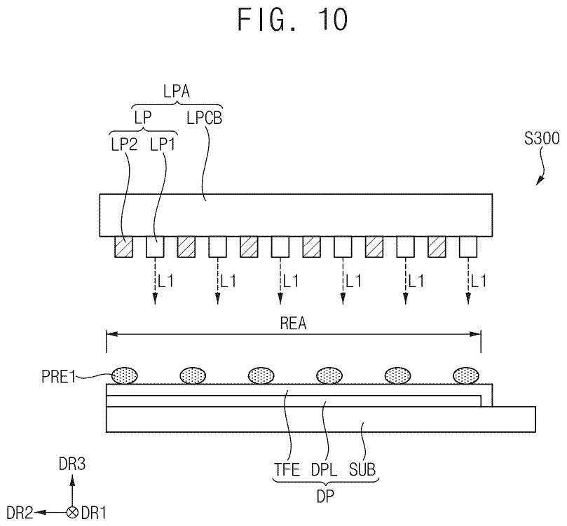

As illustrated in FIG. 10, the ultraviolet light irradiating apparatus LPA may irradiate the first ultraviolet light L1 while the ultraviolet light irradiating apparatus LPA is fixed on the preliminary resin layer PRE1. In other words, when the first ultraviolet light L1 is irradiated, the relative position between the ultraviolet light irradiating apparatus LPA and the preliminary resin layer PRE1 may be fixed.

The ultraviolet light irradiating apparatus LPA may irradiate the first ultraviolet light L1 to an entirety of the area of the preliminary resin layer PRE1. That is, the first ultraviolet emission units LP1 may be spaced apart from each other by a predetermined distance such that the first ultraviolet light L1 may be irradiated to the entirety of the area of the preliminary resin layer PRE1.

The first ultraviolet emission units LP1 may irradiate the preliminary resin layer PRE1 with the first ultraviolet light L1 having a wavelength different from the first wavelength range. Specifically, the first sub-emission unit SLP1 may irradiate the preliminary resin layer PRE1 with ultraviolet light having a wavelength of about 310 nanometers, which is smaller than the first wavelength range. The second sub-emission unit SLP2 may irradiate the preliminary resin layer PRE1 with ultraviolet light having a wavelength of about 385 nanometers, which is greater than the first wavelength range. The third sub-emission unit SLP3 may irradiate the preliminary resin layer PRE1 with ultraviolet light having a wavelength of about 405 nanometers, which is greater than the first wavelength range. The first to third sub-emission units SLP1, SLP2, and SLP3 may irradiate the ultraviolet lights to the preliminary resin layer PRE1 simultaneously. However, the disclosure is not limited thereto, and various ultraviolet lights having wavelengths different from the first wavelength range may be irradiated to the preliminary resin layer PRE1. At this time, the second ultraviolet emission units LP2 may not irradiate the second ultraviolet light to the preliminary resin layer PRE1.

As illustrated in FIG. 11, as the preliminary resin layer PRE1 is irradiated with the first ultraviolet light L1, a polymerization reaction between the oligomer and the monomer may proceed as the photopolymerization initiator is decomposed. Accordingly, an intermediate resin layer PRE2 may be formed. Here, the intermediate resin layer PRE2 may include a photopolymerization initiator that has not yet initiated a polymerization reaction. In other words, the intermediate resin layer PRE2 may include a photopolymerization initiator that has not yet been decomposed. Accordingly, the intermediate resin layer PRE2 may be defined as a resin composition in a state in which a polymerization reaction between the oligomer and the monomer may proceed further in a subsequent process.

Referring to FIGS. 12, 13, and 14, a first adhesive member ADL1 may be formed by irradiating the intermediate resin layer PRE2 with a second ultraviolet light L2 having a wavelength within the first wavelength range (S400).

As illustrated in FIG. 12, the ultraviolet light irradiating apparatus LPA may irradiate the second ultraviolet light L2 while the ultraviolet light irradiating apparatus LPA is fixed on the intermediate resin layer PRE2. In other words, when the second ultraviolet light L2 is irradiated, the relative position between the ultraviolet light irradiating apparatus LPA and the intermediate resin layer PRE2 may be fixed.

The ultraviolet light irradiating apparatus LPA may irradiate the second ultraviolet light L2 to an entirety of the area of the intermediate resin layer PRE2. That is, the second ultraviolet emission units LP2 may be spaced apart from each other by a predetermined distance such that the second ultraviolet light L2 may be irradiated to the entirety of the area of the intermediate resin layer PRE2.

The second ultraviolet emission units LP2 may irradiate the intermediate resin layer PRE2 with the second ultraviolet light L2 having a wavelength within the first wavelength range. Specifically, the second ultraviolet emission units LP2 may irradiate the intermediate resin layer PRE2 with the second ultraviolet light L2 having a wavelength of about 365 nanometers within the first wavelength range. However, the disclosure is not limited thereto, and various ultraviolet lights having wavelengths within the first wavelength range may be irradiated to the intermediate resin layer PRE2.

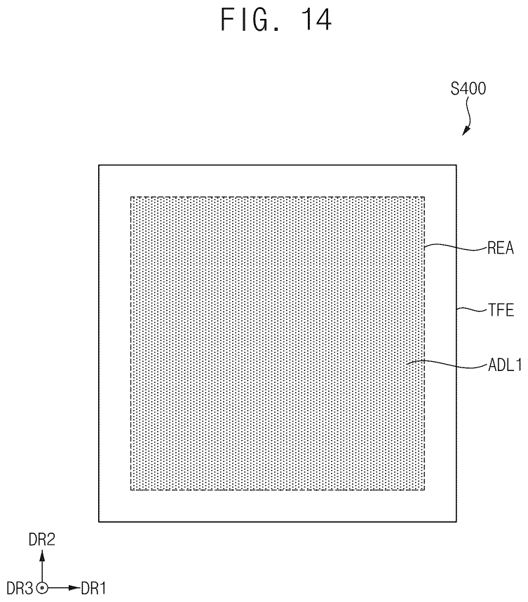

As illustrated in FIGS. 13 and 14, as the intermediate resin layer PRE2 is irradiated with the second ultraviolet light L2, a polymerization reaction between the oligomer and the monomer may be completed as the photopolymerization initiator included in the intermediate resin layer PRE2 is completely decomposed. Accordingly, the first adhesive member ADL1 including a polymer in which the oligomer and the monomer are covalently bonded may be formed. The first adhesive member ADL1 may be formed in an entirety of the resin area REA on the encapsulation layer TFE. That is, the first adhesive member ADL1 formed by irradiating the preliminary resin layer PRE1 and the intermediate resin layer PRE2 with ultraviolet lights may be an optically clear resin. The first adhesive member ADL1 may have double-sided adhesive properties.

A method (CM, refer to FIG. 5) of manufacturing an adhesive member in an embodiment of the disclosure may include forming the intermediate resin layer PRE2 by irradiating the preliminary resin layer PRE1 with the first ultraviolet light L1 having a wavelength different from the first wavelength range (S300) and forming the first adhesive member ADL1 by irradiating the intermediate resin layer PRE2 with the second ultraviolet light L2 having a wavelength within the first wavelength range (S400).

In other words, the first ultraviolet light L1 having a wavelength different from a maximum absorption wavelength of the photopolymerization initiator may be irradiated first, and the second ultraviolet light L2 having a wavelength within the range of the maximum absorption wavelength of the photopolymerization initiator may be irradiated subsequently. In this case, compared to a case where the first ultraviolet light L1 and the second ultraviolet light L2 are irradiated simultaneously from the beginning, the photopolymerization initiator may be decomposed relatively slowly. As the photopolymerization initiator decomposes relatively slowly, the polymerization reaction between the oligomer and the monomer may be completed relatively slowly. Accordingly, a length of a polymer chain formed by covalently bonding the oligomer and the monomer may be relatively increased. As the length of the polymer chain is relatively increased, the adhesive strength of the first adhesive member ADL1 including the polymer may be improved.

In an embodiment, a starting point (also referred to as a second starting point) at which the second ultraviolet light L2 is irradiated may be spaced apart from a starting point (also referred to as a first starting point) at which the first ultraviolet light L1 is irradiated by a predetermined time interval, and the predetermined time interval may be determined based on the fluidity of the preliminary resin layer PRE1. When the starting point at which the second ultraviolet light L2 is irradiated is set earlier than an appropriate time, the length of the polymer chain formed by the covalent bonding of the oligomer and the monomer may be relatively reduced. When the starting point at which the second ultraviolet light L2 is irradiated is set later than the appropriate time, the preliminary resin layer PRE1 having fluidity may flow to the outside of the display panel DP before curing of the preliminary resin layer PRE1 proceeds.

In an embodiment, as illustrated in FIG. 12, when the second ultraviolet light L2 is irradiated to the intermediate resin layer PRE2, the first ultraviolet light L1 having a wavelength different from the first wavelength range may not be irradiated. In other words, when the second ultraviolet emission units LP2 irradiate the second ultraviolet light L2 to the intermediate resin layer PRE2, the first ultraviolet emission units LP1 may not irradiate the first ultraviolet light L1.

In another embodiment, when the second ultraviolet light L2 is irradiated to the intermediate resin layer PRE2, the first ultraviolet light L1 having a wavelength different from the first wavelength range may be simultaneously irradiated to the intermediate resin layer PRE2. In other words, while the second ultraviolet emission units LP2 irradiate the second ultraviolet light L2 to the intermediate resin layer PRE2, the first ultraviolet emission units LP1 may also irradiate the first ultraviolet light L1 to the intermediate resin layer PRE2.

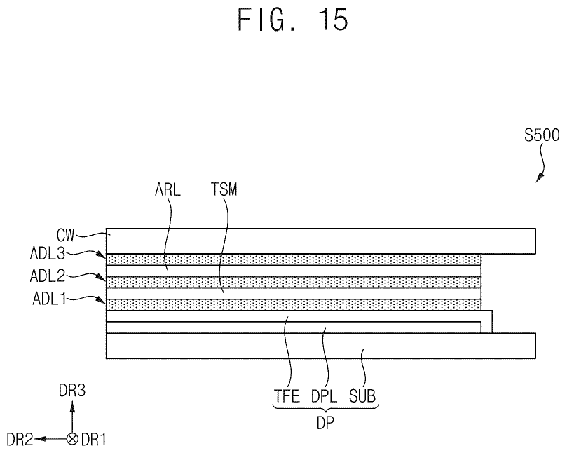

Referring to FIG. 15, the touch member TSM may be formed on the first adhesive member ADL1 (S500). The touch member TSM may cover an entirety of the first adhesive member ADL1. The touch member TSM may be attached to an upper surface of the display panel DP through the first adhesive member ADL1. Specifically, the touch member TSM may be attached to an upper surface of the encapsulation layer TFE through the first adhesive member ADL1. In an embodiment, the touch member TSM may be also referred to as a first functional member, for example.

A second adhesive member ADL2 may be formed on the touch member TSM. The second adhesive member ADL2 may include or consist of the same material as that of the first adhesive member ADL1 through the same process as that of the first adhesive member ADL1. In other words, the second adhesive member ADL2 may be formed through forming the preliminary resin layer PRE1 including a photopolymerization initiator having a maximum absorption wavelength in the first wavelength range on the touch member TSM, irradiating the preliminary resin layer PRE1 with the first ultraviolet light L1 having a wavelength different from the first wavelength range (S300), and irradiating the intermediate resin layer PRE2 with the second ultraviolet light L2 having a wavelength within the first wavelength range (S400). The second adhesive member ADL2 may be an optically clear resin. The second adhesive member ADL2 may have double-sided adhesive properties.

The anti-reflection layer ARL may be formed on the second adhesive member ADL2. The anti-reflection layer ARL may cover an entirety of the second adhesive member ADL2. The anti-reflection layer ARL may be attached to an upper surface of the touch member TSM through the second adhesive member ADL2. In an embodiment, the anti-reflection layer ARL may be also referred to as a second functional member, for example.

A third adhesive member ADL3 may be formed on the anti-reflection layer ARL. The third adhesive member ADL3 may include or consist of the same material as that of the first adhesive member ADL1 and the second adhesive member ADL2 through the same process as that of the first adhesive member ADL1 and the second adhesive member ADL2. The third adhesive member ADL3 may be an optically clear resin. The third adhesive member ADL3 may have double-sided adhesive properties.

The cover window CW may be formed on the third adhesive member ADL3. The cover window CW may partially overlap the third adhesive member ADL3. The cover window CW may be attached to an upper surface of the anti-reflection layer ARL through the third adhesive member ADL3. In an embodiment, the cover window CW may be also referred to as a third functional member, for example.

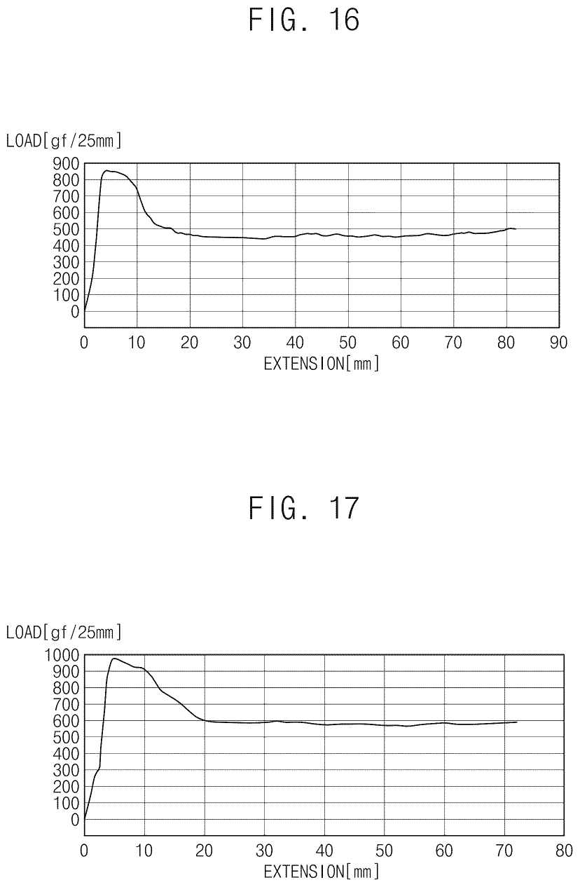

FIG. 16 is a view illustrating a strength of adhesive force of an adhesive member according to a comparative example. FIG. 17 is a view illustrating an embodiment of a strength of adhesive force of an adhesive member. Hereinafter, the effects of the disclosure will be described below with reference to FIGS. 13, 16, and 17.

A strength of adhesive force in terms of gram-force per 25 millimeters (gf/25 mm) was measured in adhesive members satisfying Comparative Example and Example. Each of the adhesive members satisfying the Comparative Example and the Embodiment was formed by irradiating a preliminary resin layer including ethyl-2,4,6-trimethylbenzoyl phenylphosphinate as a photopolymerization initiator. Ethyl-2,4,6-trimethylbenzoyl phenylphosphinate as the photopolymerization initiator has a maximum absorption wavelength of about 360 nanometers to about 370 nanometers. A width (e.g., a length in the first direction DR1) of each of the adhesive members satisfying the Comparative Example and the Embodiment is about 25 millimeters. A thickness (e.g., a length in the third direction DR3) of each of the adhesive members satisfying the Comparative Example and the Embodiment is about 50 micrometers.

The adhesive member (e.g., the first adhesive member ADL1 of FIG. 13) satisfying the Embodiment was formed by first irradiating the preliminary resin layer including ethyl-2,4,6-trimethylbenzoyl phenylphosphinate with a first ultraviolet light having a wavelength different from the maximum absorption wavelength, and secondly irradiating the preliminary resin layer with a second ultraviolet light having a wavelength within a range of the maximum absorption wavelength. Specifically, ultraviolet lights having wavelengths of about 310 nanometers, about 385 nanometers, and about 405 nanometers were first irradiated to the preliminary resin layer for about 8 seconds, and ultraviolet light having a wavelength of about 365 nanometers was secondly irradiated to the preliminary resin layer for about 8 seconds to form the adhesive member satisfying the Embodiment. When the preliminary resin layer was secondly irradiated with ultraviolet light having a wavelength of about 365 nanometers for about 8 seconds, ultraviolet lights having wavelengths of about 310 nanometers, about 385 nanometers, and about 405 nanometers were not irradiated.

The adhesive member satisfying the Comparative Example was formed by simultaneously irradiating the preliminary resin layer including ethyl-2,4,6-trimethylbenzoyl phenylphosphinate with a first ultraviolet light having a wavelength different from the maximum absorption wavelength and a second ultraviolet light having a wavelength within the range of the maximum absorption wavelength. Specifically, ultraviolet lights having wavelengths of about 310 nanometers, about 365 nanometers, about 385 nanometers, and about 405 nanometers were simultaneously irradiated to the preliminary resin layer for about 8 seconds to form the adhesive member satisfying the Comparative Example.

As a result, as illustrated in FIG. 16, the strength of adhesive force of the adhesive member satisfying the Comparative Example was measured to have a value of about 461.57 gf/25 mm. In addition, as illustrated in FIG. 17, the strength of adhesive force of the adhesive member satisfying the Embodiment was measured to have a value of about 570.39 gf/25 mm. From these results, it may be seen that compared to the adhesive strength of the adhesive member satisfying the Comparative Example, the adhesive strength of the adhesive member satisfying the Embodiment is improved by about 23.58%.

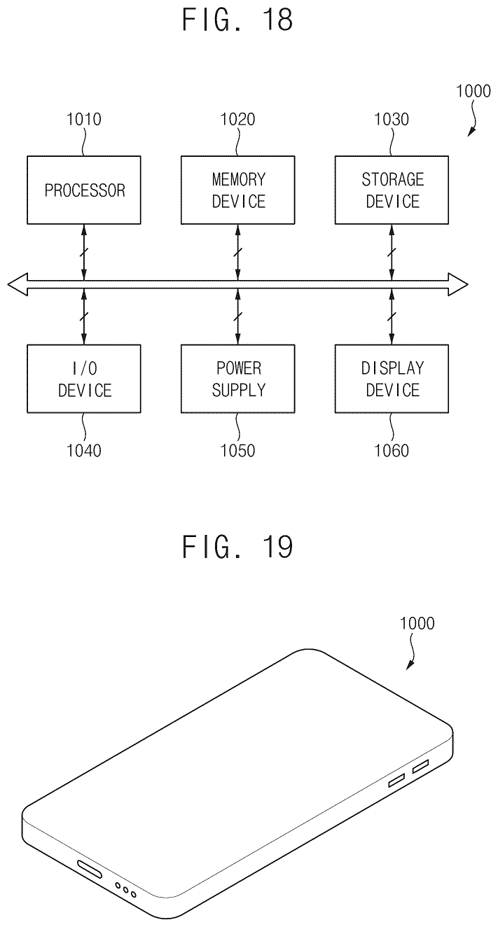

FIG. 18 is a block diagram illustrating an embodiment of an electronic device according to the disclosure. FIG. 19 is a view illustrating an example in which the electronic device of FIG. 18 is implemented as a smart phone.

Referring to FIGS. 18 and 19, an electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (“USB”) device, other systems, and the like.

In an embodiment, as illustrated in FIG. 19, the electronic device 1000 may be implemented as a smart phone. However, the electronic device 1000 is not limited thereto. For example, the electronic device 1000 may be implemented as a smart pad, a smart watch, a tablet PC, a car navigation system, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The disclosure may be applied to various display devices. In an embodiment, the disclosure is applicable to various display devices such as display devices for vehicles, ships and aircraft, portable communication devices, display devices for exhibition or information transmission, medical display devices, or the like, for example.

The foregoing is illustrative of the embodiments of the disclosure, and is not to be construed as limiting thereof. Although a few embodiments have been described with reference to the drawing figures, those skilled in the art will readily appreciate that many variations and modifications may be made therein without departing from the spirit and scope of the disclosure as defined in the appended claims.

What is claimed is:

1. A method of manufacturing an adhesive member, the method comprising:
providing a preliminary resin layer including a photopolymerization initiator having a maximum absorption wavelength in a first wavelength range;
forming an intermediate resin layer by irradiating the preliminary resin layer with a first ultraviolet light having a wavelength different from the first wavelength range; and
forming an adhesive member by irradiating the intermediate resin layer with a second ultraviolet light having a wavelength within the first wavelength range.

2. The method of claim 1, wherein
a second starting point at which the second ultraviolet light is irradiated is spaced apart from a first starting point at which the first ultraviolet light is irradiated by a predetermined time interval, and
the predetermined time interval is determined based on a fluidity of the preliminary resin layer.

3. The method of claim 1, wherein in the irradiating the second ultraviolet light to the intermediate resin layer,
the first ultraviolet light having the wavelength different from the first wavelength range is not irradiated.

4. The method of claim 1, wherein in the irradiating the second ultraviolet light to the intermediate resin layer,
the first ultraviolet light having the wavelength different from the first wavelength range is simultaneously irradiated to the intermediate resin layer.

5. The method of claim 1, wherein in the irradiating the first ultraviolet light,
the first ultraviolet light includes sub-ultraviolet lights so that a sub-ultraviolet light having a wavelength smaller than the first wavelength range and a sub-ultraviolet light having a wavelength greater than the first wavelength range among the sub-ultraviolet lights are simultaneously irradiated.

6. The method of claim 1, wherein the irradiating the first ultraviolet light and the irradiating the second ultraviolet light are performed by an ultraviolet light irradiating apparatus including a plurality of first ultraviolet emission units which irradiate the first ultraviolet light and a plurality of second ultraviolet emission units which irradiate the second ultraviolet light.

7. The method of claim 6, wherein
the ultraviolet light irradiating apparatus irradiates the first ultraviolet light while the ultraviolet light irradiating apparatus is fixed on the preliminary resin layer, and
the ultraviolet light irradiating apparatus irradiates the second ultraviolet light while the ultraviolet light irradiating apparatus is fixed on the intermediate resin layer.

8. The method of claim 7, wherein
the ultraviolet light irradiating apparatus irradiates the first ultraviolet light to an entirety of an area of the preliminary resin layer, and
the ultraviolet light irradiating apparatus irradiates the second ultraviolet light to an entirety of an area of the intermediate resin layer.

9. The method of claim 6, wherein
the plurality of first ultraviolet emission units is arranged in a matrix form in a plan view, and
the plurality of second ultraviolet emission units is arranged in a matrix form in the plan view.

10. A method of manufacturing a display device, the method comprising:
forming a preliminary resin layer including a photopolymerization initiator which has a maximum absorption wavelength in a first wavelength range on a display panel including a substrate, a display element layer, and an encapsulation layer;
forming an intermediate resin layer by irradiating the preliminary resin layer with a first ultraviolet light having a wavelength different from the first wavelength range;
forming an adhesive member by irradiating the intermediate resin layer with a second ultraviolet light having a wavelength within the first wavelength range; and
forming a functional member on the adhesive member.

11. The method of claim 10, wherein
a second starting point at which the second ultraviolet light is irradiated is spaced apart from a first starting point at which the first ultraviolet light is irradiated by a predetermined time interval, and
the predetermined time interval is determined based on a fluidity of the preliminary resin layer.

12. The method of claim 10, wherein in the irradiating the second ultraviolet light to the intermediate resin layer,
the first ultraviolet light having the wavelength different from the first wavelength range is not irradiated.

13. The method of claim 10, wherein in the irradiating the second ultraviolet light to the intermediate resin layer,
the first ultraviolet light having the wavelength different from the first wavelength range is simultaneously irradiated to the intermediate resin layer.

14. The method of claim 10, wherein in the irradiating the first ultraviolet light,
the first ultraviolet light includes sub-ultraviolet lights so that a sub-ultraviolet light having a wavelength smaller than the first wavelength range and a sub-ultraviolet light having a wavelength greater than the first wavelength range among the sub-ultraviolet lights are simultaneously irradiated.

15. The method of claim 10, wherein the preliminary resin layer is formed using an inkjet printing method.

16. The method of claim 10, wherein the functional member includes at least one of a touch member, an anti-reflection layer, and a cover window.

17. The method of claim 10, wherein the irradiating the first ultraviolet light and the irradiating the second ultraviolet light are performed by an ultraviolet light irradiating apparatus including a plurality of first ultraviolet emission units which irradiate the first ultraviolet light and a plurality of second ultraviolet emission units which irradiate the second ultraviolet light.

18. The method of claim 17, wherein
the ultraviolet light irradiating apparatus irradiates the first ultraviolet light while the ultraviolet light irradiating apparatus is fixed on the preliminary resin layer, and
the ultraviolet light irradiating apparatus irradiates the second ultraviolet light while the ultraviolet light irradiating apparatus is fixed on the intermediate resin layer.

19. The method of claim 18, wherein
the ultraviolet light irradiating apparatus irradiates the first ultraviolet light to an entirety of an area of the preliminary resin layer, and
the ultraviolet light irradiating apparatus irradiates the second ultraviolet light to an entirety of an area of the intermediate resin layer.

20. The method of claim 17, wherein
the plurality of first ultraviolet emission units is arranged in a matrix form in a plan view, and
the plurality of second ultraviolet emission units is arranged in a matrix form in the plan view.

21. An electronic device comprising:
a display device manufactured according to the method of claim 10; and
a power supply configured to provide power to the display device.
